(19) United States
(12) Patent Application Publication
(10) Pub. No.: US 2024/0402663 A1
(43) Pub. Date: Dec. 5, 2024

(54) DESIGN SYSTEM, DESIGN PROGRAM, AND DESIGN METHOD

(71) Applicant: OMRON CORPORATION, Kyoto-shi (JP)

(72) Inventors: Hiroshi YOSHIDA, Kyoto-shi (JP); Tetsuro SUGIHARA, Kyoto-shi (JP); Kenichiro MORI, Kyoto-shi (JP)

(73) Assignee: OMRON CORPORATION, Kyoto-shi (JP)

(21) Appl. No.: 18/647,148

(22) Filed: Apr. 26, 2024

(30) Foreign Application Priority Data
May 31, 2023 (JP) 2023-089472

(51) Int. Cl. G05B 15/02

(52) U.S. Cl. CPC G05B 15/02

(57) ABSTRACT

Provided is a design system for creating a control system configuration that is design information for constructing equipment including one or more apparatuses. The design system is configured to perform: a process of obtaining equipment design information of equipment; a process of obtaining from a design asset library, based on identification information included in the equipment design information, a design asset for constructing a specific apparatus; a process of creating a control system configuration based on the equipment design information and the design asset; and a process of verifying the created control system configuration based on one or more verification rules including at least one of the system configuration rules. The design asset includes one or more system configuration rules.

### CROSS REFERENCE TO RELATED APPLICATIONS

This nonprovisional application is based on Japanese Patent Application No. 2023-089472 filed on May 31, 2023 with the Japan Patent Office, the entire contents of which are hereby incorporated by reference.

### BACKGROUND OF THE INVENTION

### Field of the Invention

The present disclosure relates to a design system, a design program, and a design method.

### Description of the Background Art

In design of equipment including various apparatuses, specific specifications or the like need to be determined after concept design and basic design. Robots are frequently used as example apparatuses in recent automated equipment. For example, Japanese Patent Laying-Open No. 2015-033744 discloses a robot control apparatus and the like that facilitate creation of the work program that indicates the details of work performed by a robot.

### SUMMARY OF THE INVENTION

For example, robots for specific use can be used commonly in various pieces of equipment.

An aspect of the present disclosure has an object to provide a system and the like that can use a design asset for constructing a specific apparatus to create a control system configuration more efficiently.

According to an embodiment, a design system for creating a control system configuration, which is design information for constructing equipment including one or more apparatuses, is provided. The design system is configured to perform: a process of obtaining equipment design information of the equipment; and a process of obtaining from a design asset library, based on identification information included in the equipment design information, a design asset for constructing a specific apparatus. The design asset includes one or more system configuration rules. The design system is further configured to perform: a process of creating a control system configuration based on the equipment design information and the design asset; and a process of verifying the created control system configuration based on one or more verification rules including at least one of the system configuration rules.

With this configuration, the control system configuration can be created from the equipment design information using the design asset for constructing a specific apparatus. Also, the created control system configuration can be verified based on at least one of the system configuration rules included in the design asset. This enables more efficient creation of the control system configuration using the design asset.

The design asset may include a mechanical configuration that defines a mechanical element necessary for the specific apparatus, a control system device configuration that defines a control device necessary for operating the specific apparatus, and a control software configuration that defines software for operating the specific apparatus.

This configuration enables more efficient creation of the control system configuration using a design asset configured as a library, which includes the mechanical configuration, the control system device configuration, and the control software configuration.

The process of verifying may include a process of verifying at least one of an association between the mechanical element defined in the mechanical configuration and the control device defined in the control system device configuration, or an association between the control device defined in the control system device configuration and the software defined in the control software configuration. This configuration can guarantee suitable association of the mechanical element defined in the mechanical configuration with the control device, and suitable association of the control device defined in the control system device configuration with the software.

The design system may be further configured to perform a process of adding, according to a user's operation, a selected rule among the system configuration rules included in the design asset to the verification rules. With this configuration, for example, among the system configuration rules included in the design asset, only the rule selected according to target equipment can be included in the verification rules, thus preventing an unnecessary verification process.

The process of verifying may include a process of determining, in the created control system configuration, whether a task assigned to a controller defined in the control system device configuration agrees with a task defined in the control software configuration. This configuration can guarantee that the task defined in the created control software configuration agrees with the task defined in the control system device configuration.

The process of verifying may include a process of determining, in the created control system configuration, whether contents of a process data object of a controller defined in the control system device configuration conform to a mapping rule. This configuration can guarantee that the contents of the process data object of the controller defined in the control system device configuration conform to the mapping rule defined in the control system device configuration.

The process of verifying may include a process of determining, in the created control system configuration, whether a mechanical element mapped to a process data object of a controller defined in the control system device configuration conforms to a mechanical element definition. This configuration can guarantee that the mechanical element mapped to the process data object of the controller defined in the control system device configuration conforms to the mechanical element definition.

The process of verifying may include a process of determining, in the created control system configuration, whether any other control device connected to a low order of a controller defined in the control system device configuration conforms to a topological rule. This configuration can guarantee that in the created control system configuration, the topology of any other control device connected to the low order of the controller conforms to a predetermined rule.

According to another embodiment, a design program for creating a control system configuration, which is design information for constructing equipment including one or more apparatuses, is provided. The design program causes a computer to obtain equipment design information of the equipment; and obtain from a design asset library, based on identification information included in the equipment design information, a design asset for constructing a specific apparatus. The design asset includes one or more system configuration rules. The design program further causes the computer to: create a control system configuration based on the equipment design information and the design asset; and verify the created control system configuration based on one or more verification rules including at least one of the system configuration rules.

According to still another embodiment, a design method performed by a computer for creating a control system configuration, which is design information for constructing equipment including one or more apparatuses, is provided. The design method includes: obtaining equipment design information of the equipment; and obtaining from a design asset library, based on identification information included in the equipment design information, a design asset for constructing a specific apparatus. The design asset includes one or more system configuration rules. The design method further includes: creating a control system configuration based on the equipment design information and the design asset; and verifying the created control system configuration based on one or more verification rules including at least one of the system configuration rules.

The foregoing and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a schematic diagram showing an example design procedure using a design system according to the present embodiment.

FIG. 2 is a schematic diagram showing an example hardware configuration of the design system according to the present embodiment.

FIG. 3 is a schematic diagram showing an example hardware configuration of an information processing apparatus according to the present embodiment.

FIG. 4 is a schematic diagram showing example creation of a design asset using the design system according to the present embodiment.

FIG. 5 is a schematic diagram showing example equipment design information created in the design system according to the present embodiment.

FIG. 6 is a schematic diagram showing an example configuration of a design asset used in the design system according to the present embodiment.

FIG. 7 is a schematic diagram showing an example work capability definition of the design asset shown in FIG. 6.

FIG. 8 is a schematic diagram showing an example configuration of a control system configuration created in the design system according to the present embodiment.

FIG. 9 is a schematic diagram showing an example configuration of system configuration rules used in the design system according to the present embodiment.

FIG. 10 is a schematic diagram showing an example schema structure of the system configuration rules used in the design system according to the present embodiment.

FIG. 11 is a flowchart showing an example method of creating a control system configuration using the design system according to the present embodiment.

FIG. 12 is a schematic diagram showing an example user interface screen provided by the information processing apparatus according to the present embodiment.

FIG. 13 is a schematic diagram showing another example of the user interface screen provided by the information processing apparatus according to the present embodiment.

FIG. 14 is a schematic diagram showing an example user interface screen regarding settings of verification rules provided by the information processing apparatus according to the present embodiment.

FIG. 15 is a schematic diagram showing another example of the user interface screen regarding settings of the verification rules provided by the information processing apparatus according to the present embodiment.

FIG. 16 is a flowchart showing an example verification process by the information processing apparatus according to the present embodiment.

FIG. 17 is a schematic diagram showing an example user interface screen regarding an output of verification results provided by the information processing apparatus according to the present embodiment.

### DESCRIPTION OF THE PREFERRED EMBODIMENTS

Embodiments of the present disclosure will be described in detail with reference to the drawings. The same or corresponding elements of the drawings have the same reference characters allotted, and description thereof will not be repeated.

### <A. Design Procedure>

First, description will be given with regard to an example design procedure using a design system 1 according to the present embodiment.

Design system 1 provides an environment for designing equipment. Although a system and a process for designing automated equipment will be mainly described below, design system 1 according to the present embodiment can be used for designing any equipment in addition to the automated equipment. In design system 1, one or more design assets are applicable.

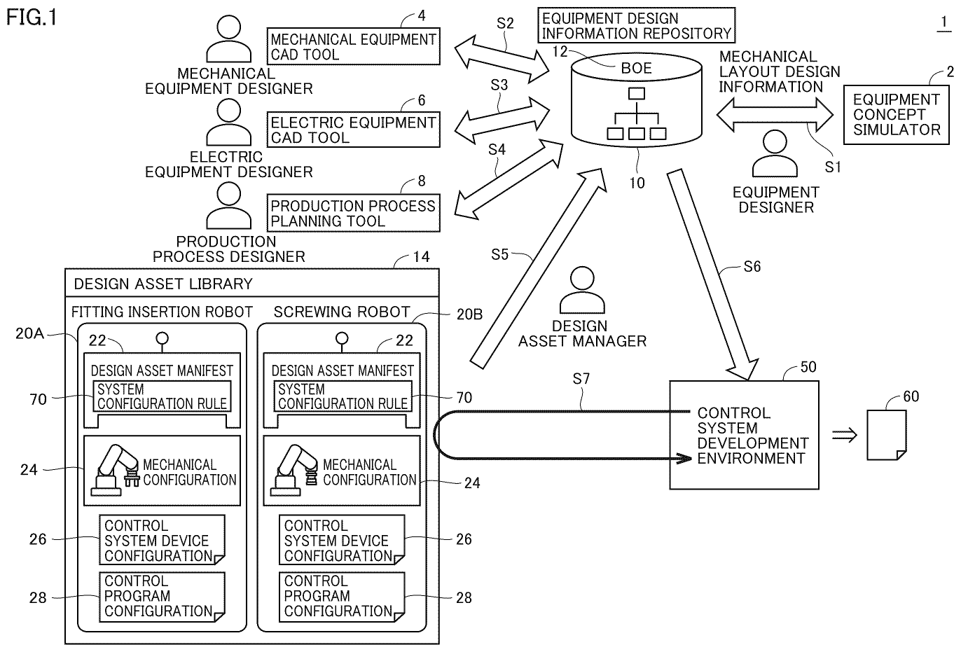

FIG. 1 is a schematic diagram showing an example design procedure using design system 1 according to the present embodiment. FIG. 1 mainly shows a process procedure in concept design and basic design of equipment. The concept design and the basic design of equipment are a design process to study the physical configuration and operation of the equipment. In the concept design and the basic design of equipment, a BOE (Bill of Equipment) 12, which is design information, is created. BOE 12 is stored in equipment design information repository 10.

At the previous stage of the concept design and the basic design of equipment, design of a product to be manufactured (product design) and design of the process for manufacturing a designed product (process design) have been performed. In order to implement the process previously designed, an equipment designer uses an equipment concept simulator 2 to determine an apparatus layout indicating apparatuses to be included in the equipment and related design information (step S1). BOE 12 includes the determined apparatus layout and the determined design information.

In addition to the equipment designer, a mechanical equipment designer, an electric equipment designer, and a production process designer may construct BOE 12.

For example, the mechanical equipment designer uses a mechanical equipment computer aided design (CAD) tool 4 to add design information regarding the mechanical equipment to BOE 12 (step S2). The electric equipment designer uses an electric equipment CAD tool 6 to add design information regarding electric equipment to BOE 12 (step S3). The production process designer uses a production process planning tool 8 to add information regarding a production process to BOE 12 (step S4).

In creation of BOE 12, the equipment designer (or any other designer) also determines whether to adopt one or more design assets 20 registered with a design asset library 14 (step S5).

Design asset 20 includes information for constructing a specific apparatus. Design asset 20 includes information on packaged apparatuses designed in advance. Design asset 20 is provided for constructing a specific apparatus and may be created by use. The specific apparatus may include, for example, a robot for specific use.

Design asset 20 includes, by way of example, a mechanical configuration 24, a control system device configuration 26, and a control software configuration 28. Mechanical configuration 24 defines mechanical elements necessary for the specific apparatus. Control system device configuration 26 defines a control device necessary for operating the specific apparatus. The control device includes, for example, a controller such as programmable logic controller (PLC), an input/output (IO) unit, and a communication unit. Control software configuration 28 defines software for operating the specific apparatus. Design asset 20 further includes a design asset manifest 22 describing, for example, the applicable scope of, and constraints on, design asset 20.

FIG. 1 shows an example in which a design asset 20A, which defines a fitting insertion robot, and a design asset 20B, which defines a screwing robot, are registered with design asset library 14. The registration of design asset 20 with design asset library 14 may be managed by a design asset manager.

The fitting insertion robot is a robot for fitting and inserting a first component into an opening formed in a second component. The screwing robot is a robot for moving a screw to a screw hole formed in a component to fasten the screw into the screw hole.

BOE 12 is created through the procedure as described above. Subsequently, a control system configuration 60, which is design information defined at a granularity necessary for actually constructing equipment, is created according to the created BOE 12. Control system configuration 60 is design information for constructing equipment including one or more apparatuses.

Specifically, the designer of the control system incorporates BOE 12 in a control system development environment 50 and designs a control system (step S6). At this time, the designer of the control system imports design asset 20 described in BOE 12 (step S7). Control system configuration 60 created includes, for example, a control system device configuration that defines a control device and a control component (e.g., an IO unit and a communication unit), and a control software configuration that defines software executed in the control device.

In design system 1 according to the present embodiment, each of design assets 20 includes system configuration rules 70 in addition to control system device configuration 26 and control software configuration 28. System configuration rules 70 may be included in design asset manifest 22. In control system development environment 50, thus, control system configuration 60 can be created efficiently using control system device configuration 26 and control software configuration 28 of design asset 20, according to system configuration rules 70. Control system development environment 50 can also verify the created control system configuration 60, based on system configuration rules 70 of design asset 20. Control system development environment 50 can further propose alterations or the like based on the verification results of control system configuration 60. System configuration rules 70 will be described later in detail.

### <B. Example Hardware Configuration of Design System 1>

Next, an example hardware configuration of design system 1 according to the present embodiment will be described.

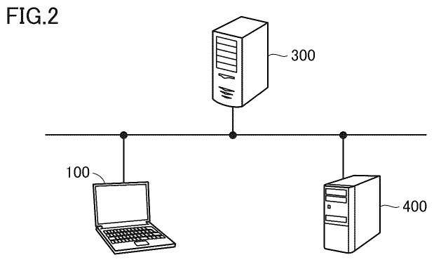

FIG. 2 is a schematic diagram showing an example hardware configuration of design system 1 according to the present embodiment. Referring to FIG. 2, design system 1 includes an information processing apparatus 100, an equipment design server 300, and a design asset server 400, by way of example.

Information processing apparatus 100 provides control system development environment 50. Equipment design server 300 stores BOE 12 that is equipment design information. Design asset server 400 has design asset library 14.

At least some of the functions of equipment design server 300 and design asset server 400 may be implemented in information processing apparatus 100.

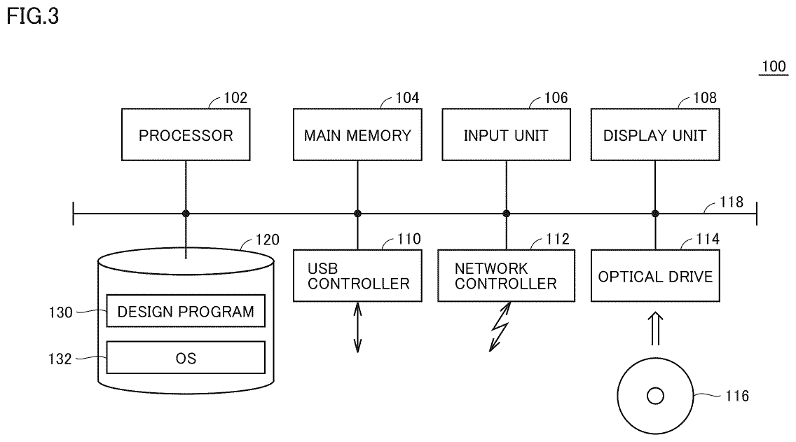

FIG. 3 is a schematic diagram showing an example hardware configuration of information processing apparatus 100 according to the present embodiment. Referring to FIG. 3, information processing apparatus 100, which is a computer, includes a processor 102 such as central processing unit (CPU) or graphics processing unit (GPU), a main memory 104, an input unit 106, a display unit 108, a universal serial bus (USB) controller 110, a network controller 112, an optical drive 114, and a storage 120. These components are connected by a bus 118.

Processor 102 reads various programs stored in storage 120, deploys the read programs to main memory 104 for execution, thereby implementing a process necessary in information processing apparatus 100.

Main memory 104 includes, for example, a volatile storage device such as dynamic random access memory (DRAM) or static random access memory (SRAM). Storage 120 includes, for example, a non-volatile storage device such as solid state drive (SSD) or hard disk drive (HDD).

Input unit 106, which includes a mouse, a keyboard, a touch panel, or the like, accepts an instruction from the user. Display unit 108, which includes a display, various indicators, or the like, outputs a processing result from processor 102.

USB controller 110 exchanges data with any device via USB connection. Network controller 112 exchanges data with any information processing apparatus over any network.

Optical drive 114 reads a program and data from a recording medium 116 (e.g., an optical recording medium such as digital versatile disc (DVD)) that non-transiently stores a computer-readable program, and stores the program and data in storage 120 or the like.

Various programs executed in information processing apparatus 100 may be installed via computer-readable recording medium 116, and may be installed by being downloaded from any server on the network.

Storage 120 typically stores an OS 132, which implements an environment for executing a program, and a design program 130. A necessary program other than the program shown in FIG. 3 may be stored in storage 120.

Design program 130 includes a computer-readable code for providing control system development environment 50.

Although FIG. 3 shows a configuration example in which one or more processors execute a program to provide necessary functions, some or all of the provided functions may be implemented using a hard-wired circuit (e.g., an application specific integrated circuit (ASIC) or a field-programmable gate array (FPGA)).

Information processing apparatus 100 may be implemented using a plurality of computing resources.

### <C. Application of Design Asset 20 in Concept Design and Basic Design of Equipment>

Next, an application example of design asset 20 in concept design and basic design of equipment will be described.

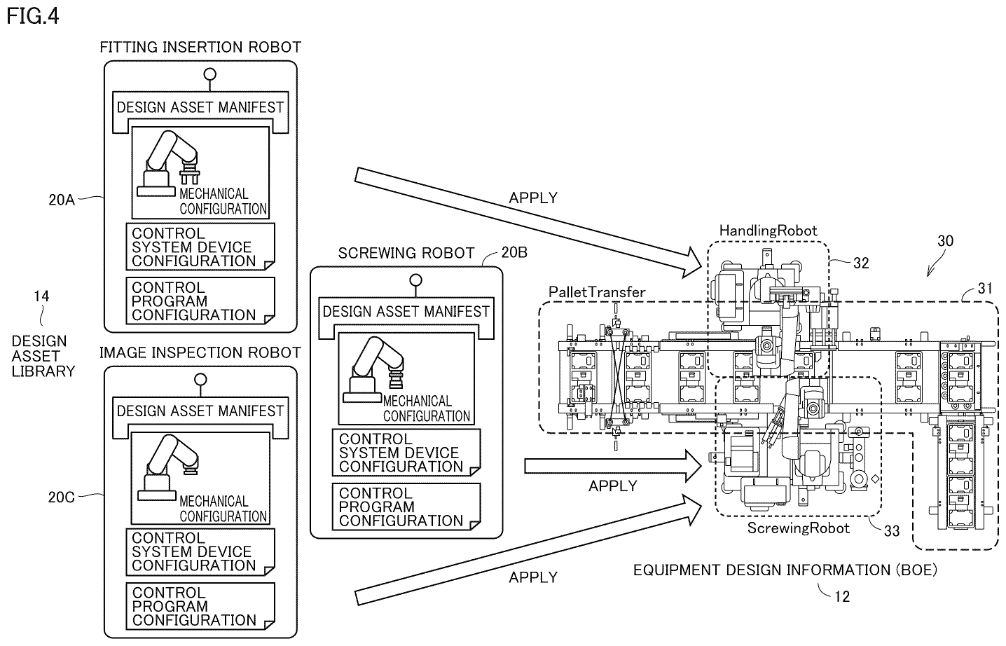

FIG. 4 is a schematic diagram showing example creation of design asset 20 using design system 1 according to the present embodiment. Equipment 30 shown in FIG. 4 includes a conveyor 31 (PalletTransfer) that transfers a pallet on which workpieces and components are mounted. On the opposite sides of conveyor 31, a robot 32 (HandlingRobot) for fitting the component with the workpiece mounted on the pallet for insertion, and a robot 33 (ScrewingRobot) for screwing the component fitted with the workpiece are arranged.

Design asset 20A (fitting insertion robot) registered with design asset library 14 is applicable as the design information of robot 32. Design asset 20B (screwing robot) and a design asset 20C (image inspection robot) are applicable as the design information of robot 33.

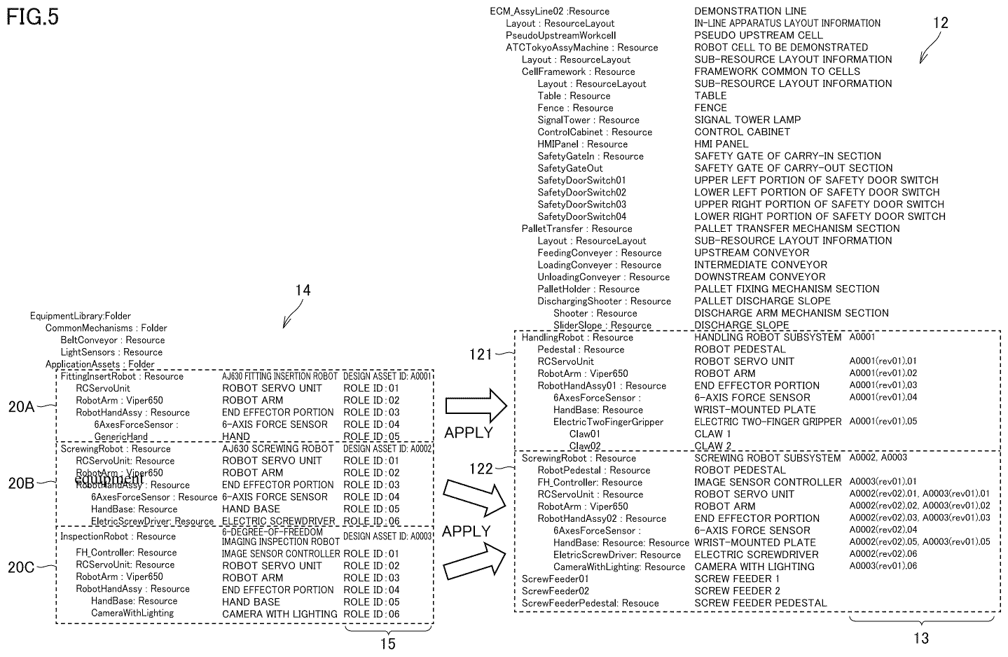

FIG. 5 is a schematic diagram showing example equipment design information created in design system 1 according to the present embodiment. FIG. 5 shows an example in which the design asset as shown in FIG. 4 is applied.

Referring to FIG. 5, BOE 12 includes design information 121 to which design asset 20A is applied, and design information 122 to which design asset 20B and design asset 20C are applied, in addition to the layout information of the apparatuses constituting equipment 30.

Each of design assets 20A, 20B, 20C includes, as additional information 15, a unique design asset ID for specifying its individual design asset. Each of design assets 20A, 20B, 20C includes one or more elements. Additional information 15 includes a role ID indicating a role that each element included in a design asset plays in the design asset.

Design information 121 and design information 122 of BOE 12 to which the design asset is applied include, as additional information, a design asset ID indicating the applied design asset, revision information 13, and a role ID indicating a role played by each element. The revision information 13 is stored in design asset manifest 22 (see FIG. 1, for example) of the design asset.

In control system development environment 50, control system configuration 60 is created based on the design information described in BOE 12.

### <D. Design Asset 20>

Next, design asset 20 registered with design asset library 14 will be described in detail.

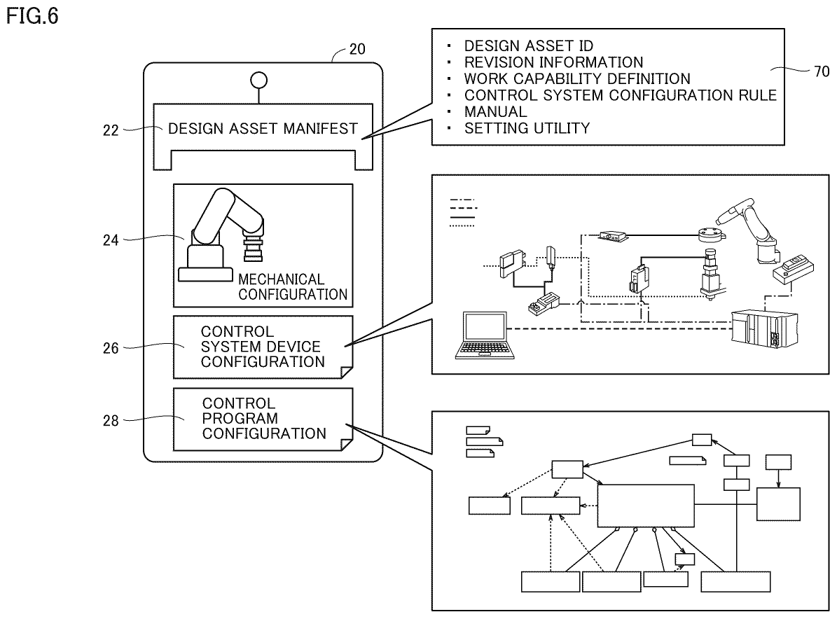

FIG. 6 is a schematic diagram showing an example configuration of design asset 20 used in design system 1 according to the present embodiment. Referring to FIG. 6, design asset 20 includes design asset manifest 22, mechanical configuration 24, control system device configuration 26, and control software configuration 28.

Design asset manifest 22 includes a design asset ID for specifying each design asset, revision information, a work capability definition, system configuration rules 70, a manual, and a setting utility.

Mechanical configuration 24 defines, for example, elements of an apparatus.

Control system device configuration 26 defines, for example, a control device, an IO unit, and a communication unit. The definition of control system device configuration 26 corresponds to the element defined in mechanical configuration 24.

Control software configuration 28 defines software for operating an apparatus. Control software configuration 28 corresponds to the element defined in mechanical configuration 24 and the element defined in control system device configuration 26.

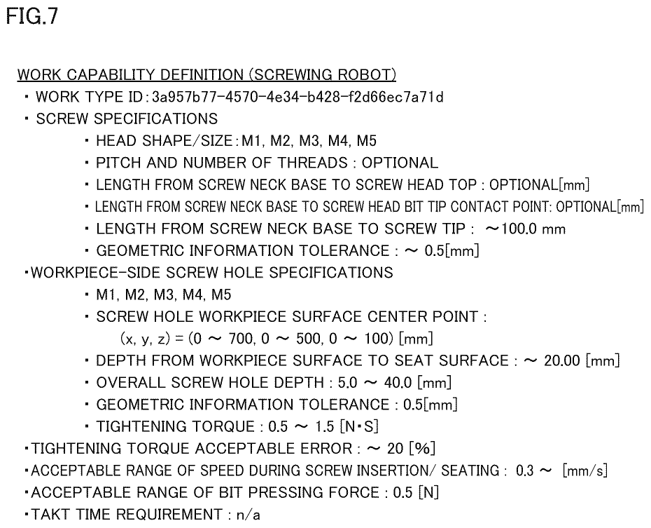

FIG. 7 is a schematic diagram showing an example work capability definition of design asset 20 shown in FIG. 6. FIG. 7 shows an example work capability definition of the screwing robot. Referring to FIG. 7, the work capability definition includes information regarding the capability of the screwing robot defined in design asset 20.

The work capability definition shown in FIG. 7 includes, for example, a unique work type ID for specifying work that can be performed, specifications of a screw capable of screwing, specifications of a screw hole, an acceptable error of a tightening torque, an acceptable range of speed during insertion/seating of a screw, an acceptable range of bit pressing force, and a tact time requirement.

The equipment designer checks the work capability definition and then determines whether to apply design asset 20.

### <E. Control System Configuration 60>

Next, control system configuration 60 created in control system development environment 50 will be described.

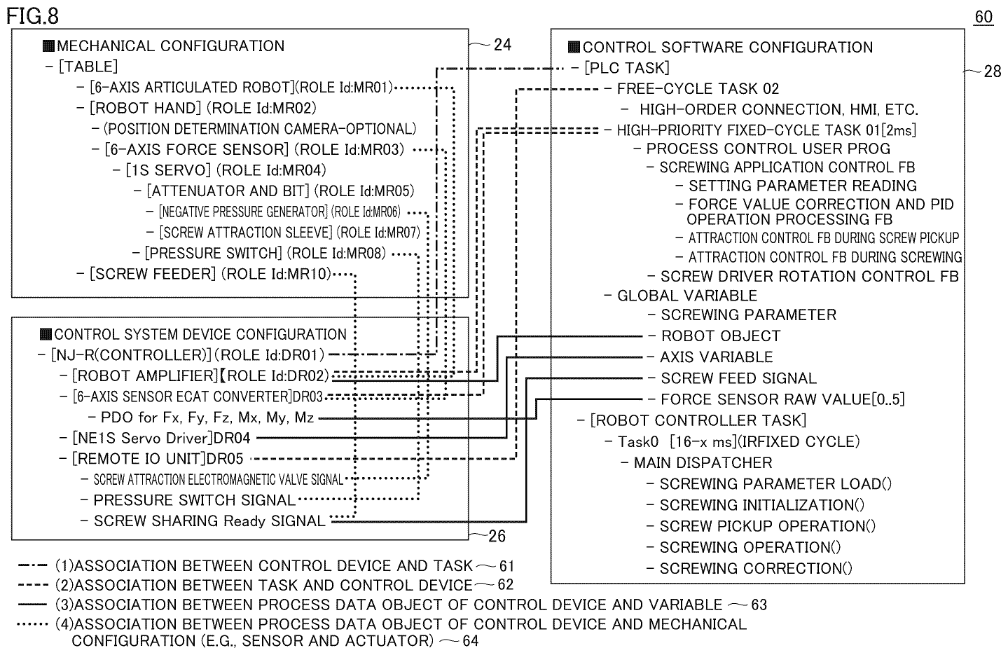

FIG. 8 is a schematic diagram showing an example configuration of control system configuration 60 created in design system 1 according to the present embodiment.

Referring to FIG. 8, control system configuration 60 includes mechanical configuration 24, control system device configuration 26, and control software configuration 28. In control system configuration 60, at least some of the elements of mechanical configuration 24, at least some of the elements of control system device configuration 26, and at least some of the elements of control software configuration 28 are associated with each other according to system configuration rules 70.

In other words, in order to implement a control algorithm specific to design asset 20, setting needs to be performed to suitably interconnect a mechanical element (specifically, a sensor for detecting, for example, a position of an element, and an actuator for driving an element) of mechanical configuration 24, an electric element (e.g., a control device and a field network) of control system device configuration 26, and a software element (e.g., a control program executed in a control device and a variable referred to in the control program) of control software configuration 28.

By way of example, FIG. 8 shows four types of example associations as described below.
(1) An association 61 between a control device and a task
(2) An association 62 between a task and a control target (control device)
(3) An association 63 between a process data object of a control device and a variable
(4) An association 64 between a process data object of a control device and a mechanical configuration (e.g., a sensor and an actuator)

A process data object (PDO) of a control device is an object for managing data transmitted/received between the control device and the sensor, the actuator. The process data object shows the structure of data that is periodically transmitted over a field network.

In order to implement a control algorithm, a control cycle necessary for each series of connected control sequences (e.g., a series of control sequences including reading of a sensor value, execution of a control operation, and reflecting of an operation result in an actuator) is defined as a constraint. Setting needs to be performed to satisfy the constraint also in the control system to which the control asset is applied.

Further, in a perspective specific to design asset 20 (e.g., safety, maintainability, ease of handling when handling an abnormality), the element and setting may have constraints. An example of such constraints is the need to determine a topology of a field network while taking into account the order in which the control device is activated after power-on.

### <F. System Configuration Rules 70>

Next, an example configuration of system configuration rules 70 will be described.

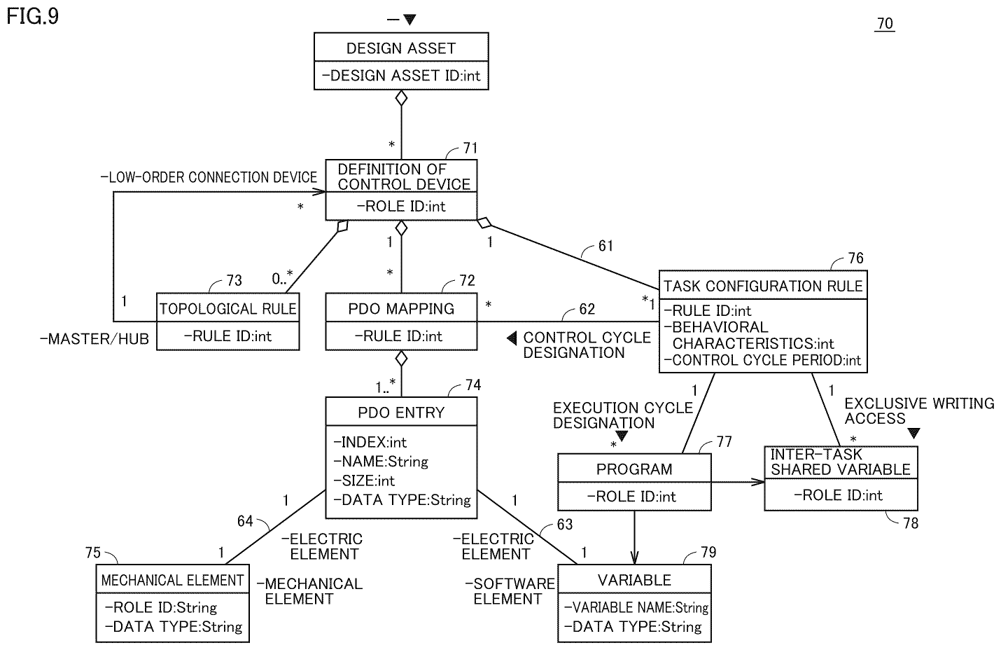

FIG. 9 is a schematic diagram showing an example configuration of system configuration rules 70 used in design system 1 according to the present embodiment. Referring to FIG. 9, each of system configuration rules 70 is provided with a design asset ID.

System configuration rules 70 include a definition 71 of a control device, a PDO mapping rule 72, a topological rule 73, a PDO entry 74, a mechanical element definition 75, a task configuration rule 76, a program definition 77, an inner-task shared variable definition 78, and a variable definition 79.

Definition 71 of a control device includes a role ID assigned for each element registered as a control device. PDO mapping rule 72 includes a setting rule of a process data object of the control device. Topological rule 73 includes a rule regarding topology between elements of the control device.

PDO entry 74 includes designation of a process data object of the control device. Mechanical element definition 75 includes designation of a mechanical element to be associated with a program data object. Task configuration rule 76 includes designation of a task to be performed. Program definition 77 includes designation of a program to be evaluated in the task. Inner-task shared variable definition 78 includes designation of a common variable to be exclusively accessed in the task. Variable definition 79 includes designation of a variable to be mapped to a process data object.

Association 61 between a control device and a task shown in FIG. 8 is determined based on definition 71 of a control device and task configuration rule 76. Association 62 between a task and a control device shown in FIG. 8 is determined based on PDO mapping rule 72 and task configuration rule 76. Association 63 between a process data object of a control device and a variable shown in FIG. 8 is determined based on PDO entry 74 and variable definition 79. Association 64 between a process data object of a control device and a mechanical configuration shown in FIG. 8 is determined based on PDO entry 74 and mechanical element definition 75.

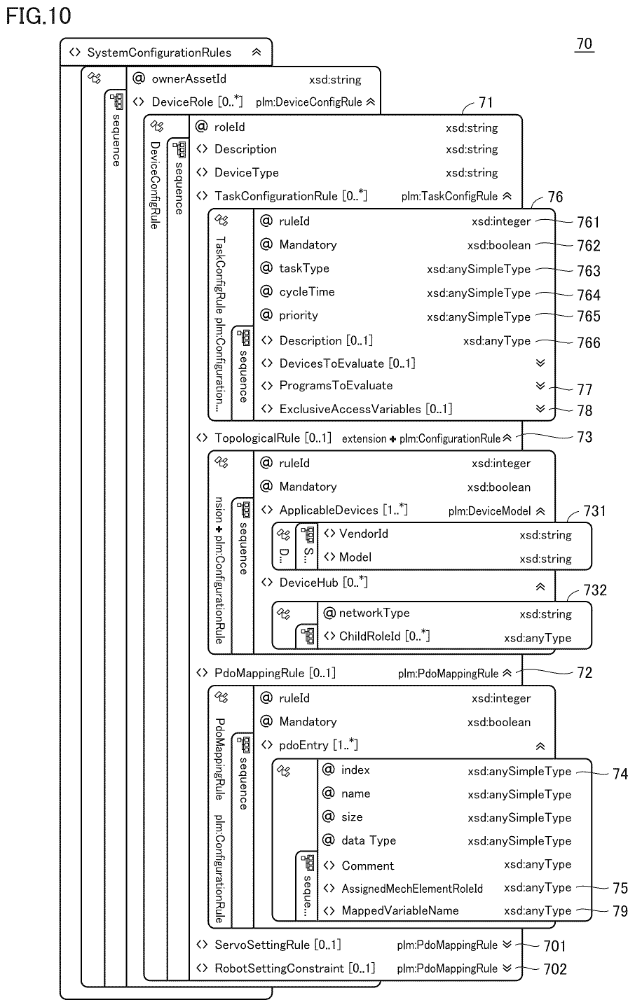

FIG. 10 is a schematic diagram showing an example schema structure of system configuration rules 70 used in design system 1 according to the present embodiment. Referring to FIG. 10, system configuration rules 70 are defined for each design asset ID. System configuration rules 70 include definition 71 of a control device. Definition 71 of a control device defines a necessary control device. Each control device is provided with a role ID. In other words, a necessary control device is specified by the role ID.

Task configuration rule 76 includes a rule ID 761 for specifying each task configuration rule, a flag 762 indicating whether to strictly apply a rule, and a task class 763 (e.g., fixed-cycle task, free-cycle task, event-driven task). Task configuration rule 76 is defined when a control device to be associated is a controller such as PLC.

Task configuration rule 76 may include a cycle time 764 (for fixed cycle task) and a task processing priority 765.

Task configuration rule 76 includes a list 766 of control devices controlled by the task. Task configuration rule 76 includes a program definition 77 and an inner-task shared variable definition 78.

Definition 71 of a control device includes a topological rule 73. Topological rule 73 includes, as sub-elements, a list 731 of control devices (including a specific vendor and a specific model name of a control device) that have been confirmed to be applicable and a list 732 of control devices that are to be connected to the low order of the control device (when the control device functions as a connection hub or a network master).

Definition 71 of a control device includes a PDO mapping rule 72, which is a setting rule of the process data object of the control device.

PDO mapping rule 72 includes, as a sub-element, a PDO entry 74, which is definition of the process data object. PDO entry 74 includes a mechanical element definition 75, which is designation of a mechanical element (e.g., a sensor and an actuator) to be associated with the program data object, and a variable definition 79, which is designation of a variable to be mapped to the process data object.

System configuration rules 70 may include a setting 701, which is specific to the case where the control device is a servo, and a setting 702, which is specific to the case where the control device is a robot.

### <G. Method of Generating Control System Configuration 60>

Next, an example method of creating control system configuration 60 using design system 1 will be described.

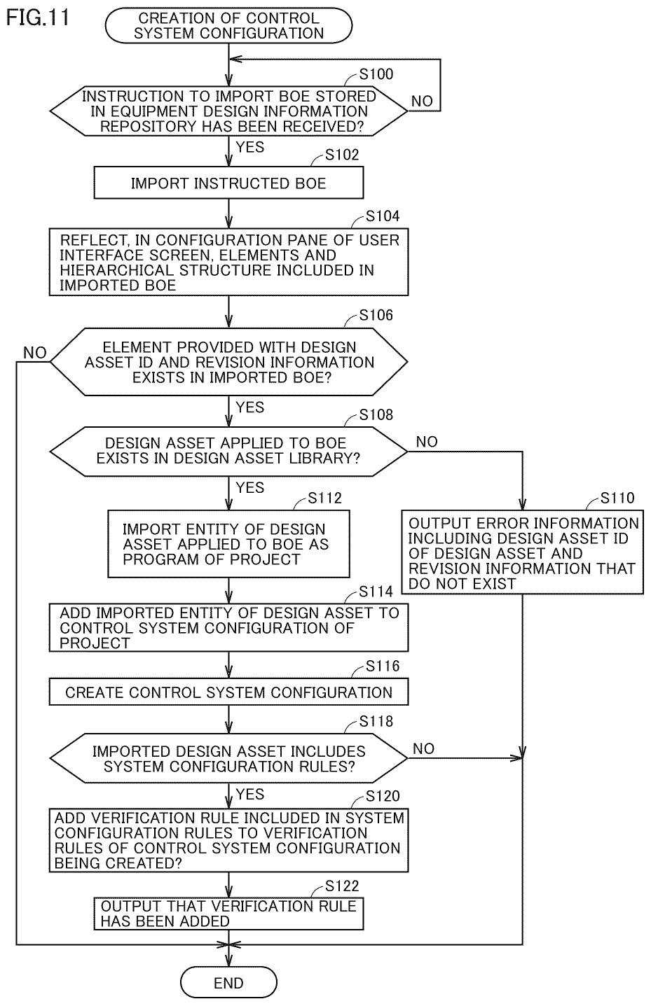

FIG. 11 is a flowchart showing an example method of creating control system configuration 60 using design system 1 according to the present embodiment. Each step shown in FIG. 11 may be implemented as processor 102 of information processing apparatus 100 executes design program 130 (see FIG. 3).

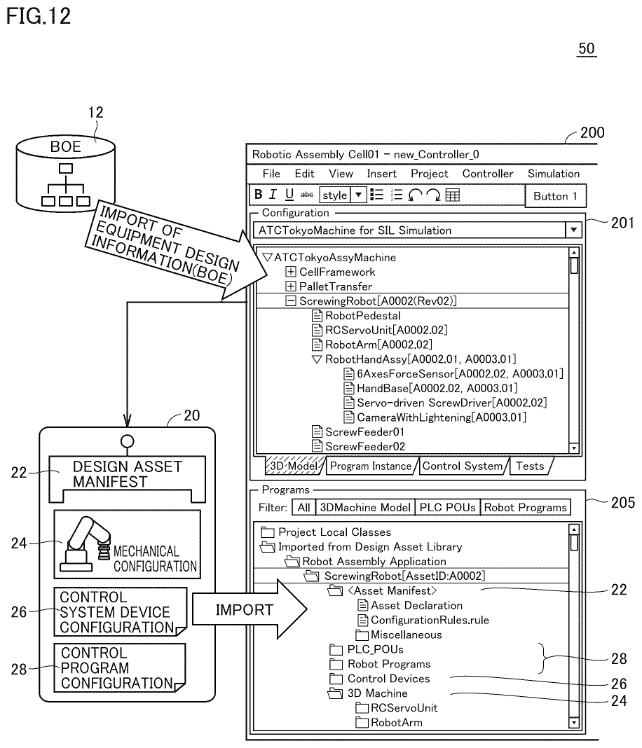

Referring to FIG. 11, upon receipt of an instruction to import BOE 12 (equipment configuration information) stored in equipment design information repository 10 (YES at step S100), information processing apparatus 100 imports the instructed BOE 12 (step S102). Information processing apparatus 100 reflects, in a configuration pane 201 of a user interface screen 200, elements and a hierarchical structure included in the imported BOE 12 (step S104) (see FIG. 12). Thus, information processing apparatus 100 obtains equipment design information (BOE 12) of equipment according to, for example, a user's operation.

Information processing apparatus 100 determines whether an element provided with a design asset ID and revision information exists in the imported BOE 12 (step S106). In other words, information processing apparatus 100 determines whether design asset 20 is applied to BOE 12.

When an element provided with a design asset ID and revision information does not exist in the imported BOE 12 (NO at step S106), the process ends.

When an element provided with a design asset ID and revision information exists in the imported BOE 12 (YES at step S106), information processing apparatus 100 determines whether design asset 20 applied to BOE 12 exists in design asset library 14, based on the design asset ID and the revision information provided to the element included in BOE 12 (step S108).

When design asset 20 applied to BOE 12 does not exist (NO at step S108), information processing apparatus 100 outputs error information including the design asset ID of design asset 20 and the revision information that do not exist (step S110). Then, the process ends.

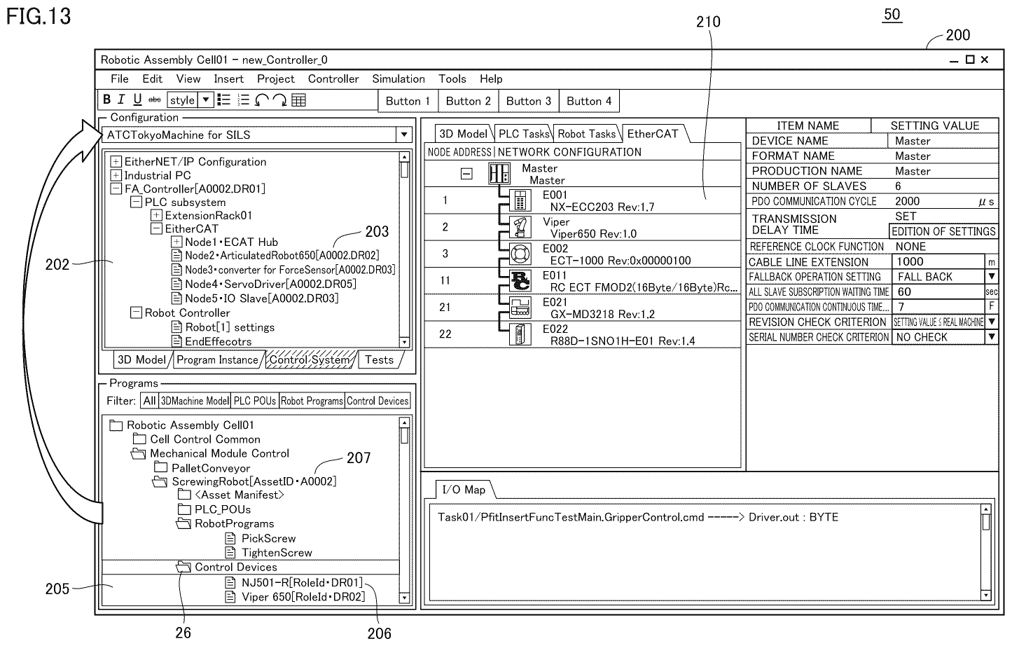

When design asset 20 applied to BOE 12 exists (YES at step S108), information processing apparatus 100 imports, as a project program, an entity of design asset 20 applied to BOE 12 (step S112) (see FIG. 13). Information processing apparatus 100 then adds the imported entity of design asset 20 to the control system configuration of the project (step S114) (see FIG. 13). Thus, information processing apparatus 100 obtains design asset 20 from design asset library 14 based on the identification information (design asset ID and revision information) included in the equipment design information (BOE 12).

Information processing apparatus 100 creates control system configuration 60 based on the equipment design information (BOE 12) and one or more imported design assets 20 (step S116). Control system configuration 60 may be created as at least part of the project. Alternatively, control system configuration 60 may include an object-like program in addition to the design information.

The processes of step S112 to step S116 may be performed according to a user's operation.

Information processing apparatus 100 determines whether the imported design asset 20 includes system configuration rules 70 (step S118). When the imported design asset 20 does not include system configuration rules 70 (NO at step S118), the process ends.

When the imported design asset 20 includes system configuration rules 70 (YES at step S118), information processing apparatus 100 adds a verification rule included in system configuration rules 70 to the verification rules of control system configuration 60 being created (step S120). Information processing apparatus 100 outputs that the verification rule has been added (step S122). Then, the process ends.

System configuration rules 70 may include a setting that needs not to be used for verification as described later. A rule to be verified among the rules included in system configuration rules 70 will also be referred to as a “verification rule” below. The verification rule can be set based on system configuration rules 70 included in design asset 20. Also, the verification rule can be set independently of system configuration rules 70 included in design asset 20.

Through the verification and the like as described later, system configuration rules 70 are finally output.

FIG. 12 is a schematic diagram showing an example of user interface screen 200 provided by information processing apparatus 100 according to the present embodiment. User interface screen 200 is provided in control system development environment 50. Referring to FIG. 12, user interface screen 200 includes configuration pane 201 and a program pane 205.

When the user imports BOE 12 that is equipment design information to control system development environment 50, an element included in the imported BOE 12 is displayed in configuration pane 201. The imported BOE 12 is associated with control system configuration 60 to be created.

Referring to the design asset ID indicated by the element included in BOE 12 displayed in configuration pane 201, the user imports necessary design asset 20 from design asset library 14 to control system development environment 50 (program pane 205). The contents of the imported design asset 20 are displayed in program pane 205.

In program pane 205, the imported design asset 20 may be expressed as a folder with design asset definition information. In program pane 205, any folder may be designated as a design asset. When any folder is designated, control system development environment 50 may display a dialog for accepting necessary information as design asset manifest 22 in association with the designated folder.

The design asset created or updated in control system development environment 50 may be exported to design asset library 14.

In control system development environment 50, as in the case where a program and a type are used, design asset 20 can be applied to creation of control system configuration 60 by dragging and dropping a target folder or an individual item to program pane 205. As a result of application of design asset 20, a control device defined in design asset 20 is added to control system configuration 60. In addition, a design asset ID corresponding to the added control device and a role ID of each control device are recorded. The design asset ID and the role ID are referred to in verification based on system configuration rules 70 included in design asset 20.

FIG. 13 is a schematic diagram showing another example of user interface screen 200 provided by information processing apparatus 100 according to the present embodiment.

Referring to FIG. 13, in control system development environment 50, one or more control devices defined in control system device configuration 26 included in the applied design asset 20 are added to control system configuration 60. On user interface screen 200, a control device configuration display 210 reflecting the added one or more control devices is enabled.

More specifically, as the user performs a predetermined operation in configuration pane 202, the control devices included in the folder of control system device configuration 26 displayed in program pane 205 are added to configuration pane 202. Each control device included in control system device configuration 26 is provided with a role ID 206. In program pane 205, a design asset ID 207 of design asset 20 is displayed.

Each control device added to configuration pane 202 is provided with additional information 203 including design asset ID 207 and role ID 206. Additional information 203 is used to verify whether the settings regarding the control device are in accordance with system configuration rules 70.

### <H. Verification>

Next, verification based on the verification rules (system configuration rules 70) will be described.

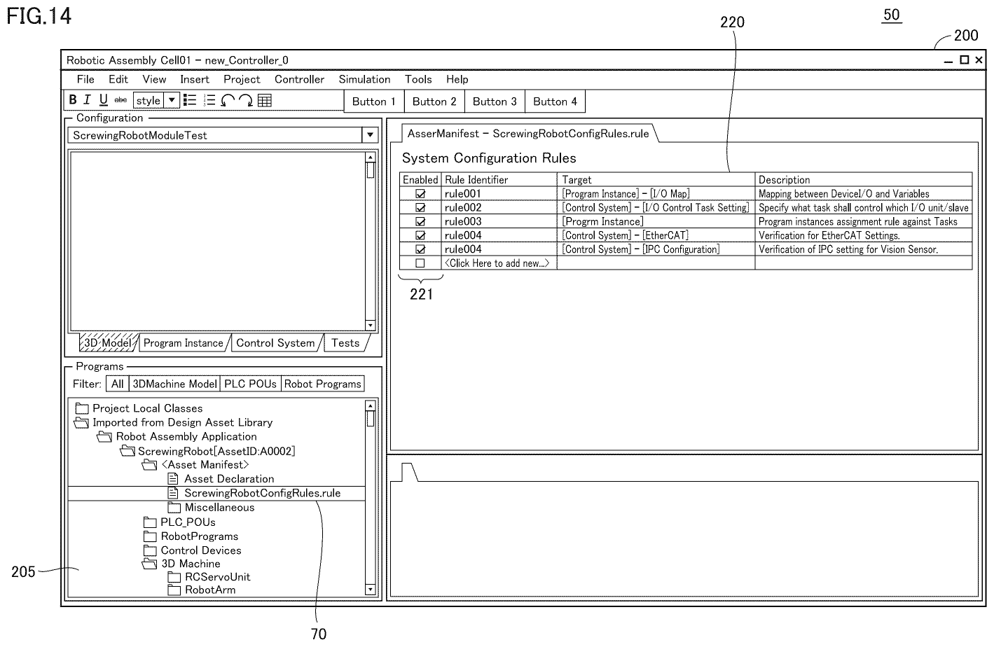

FIG. 14 is a schematic diagram showing an example of user interface screen 200 regarding settings of the verification rules provided by information processing apparatus 100 according to the present embodiment. Referring to FIG. 14, upon selection of a folder of system configuration rules 70 displayed in program pane 205 of user interface screen 200, a system configuration rule display 220 indicating system configuration rules 70 is enabled.

Each rule included in system configuration rule display 220 may be determined whether to be included in the verification rules according to whether a checkbox 221 is checked.

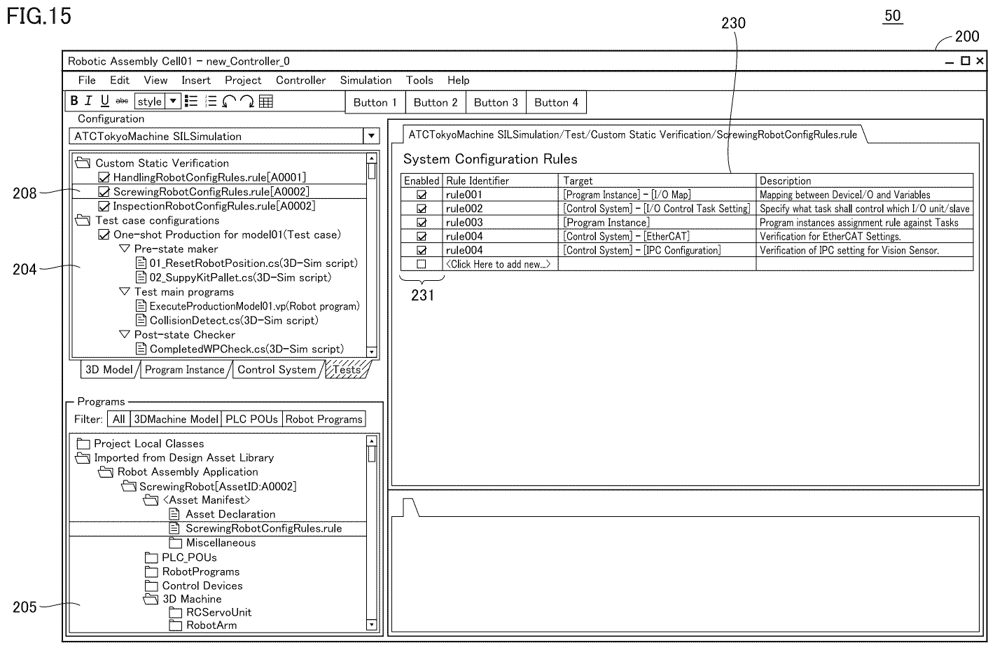

FIG. 15 is a schematic diagram showing another example of user interface screen 200 regarding settings of the verification rules provided by information processing apparatus 100 according to the present embodiment. Referring to FIG. 15, when design asset 20 is applied to control system configuration 60, system configuration rules 70 included in design asset 20 are also applied.

When a folder 208 of system configuration rules 70 displayed in verification pane 204 is selected, a system configuration rule list 230 indicating system configuration rules 70 is displayed.

Each rule included in system configuration rule list 230 is determined whether to be included in the verification rules according to whether checkbox 231 is checked. In other words, information processing apparatus 100 adds, according to a user's operation, the selected rule among system configuration rules 70 included in design asset 20 to the verification rules.

For control system configuration 60, any rule can be added to the verification rules.

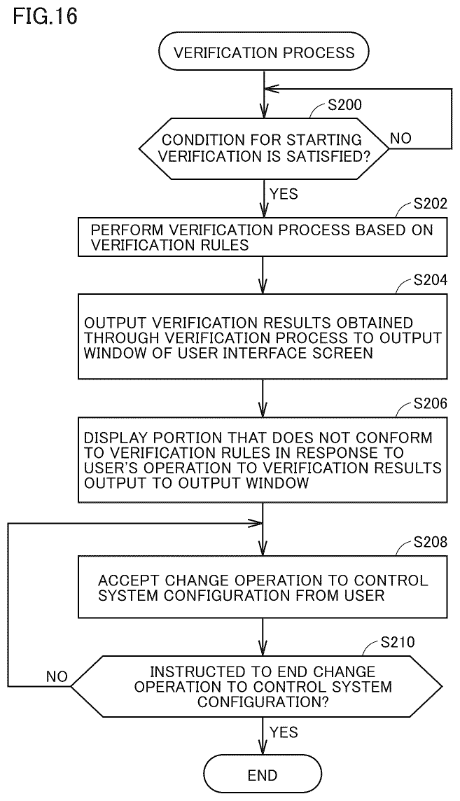

FIG. 16 is a flowchart showing an example verification process by information processing apparatus 100 according to the present embodiment. Each step shown in FIG. 16 may be implemented as processor 102 of information processing apparatus 100 executes design program 130 (see FIG. 3).

Information processing apparatus 100 verifies the created control system configuration 60 based on the verification rules including at least one of system configuration rules 70. More specifically, the process shown in FIG. 16 is performed.

When the condition for starting verification is satisfied (YES at step S200), information processing apparatus 100 performs the verification process based on the verification rules (step S202).

Examples of the condition for starting verification include saving of a project, compiling of a project, building of a project, and an explicit instruction from a user to start verification.

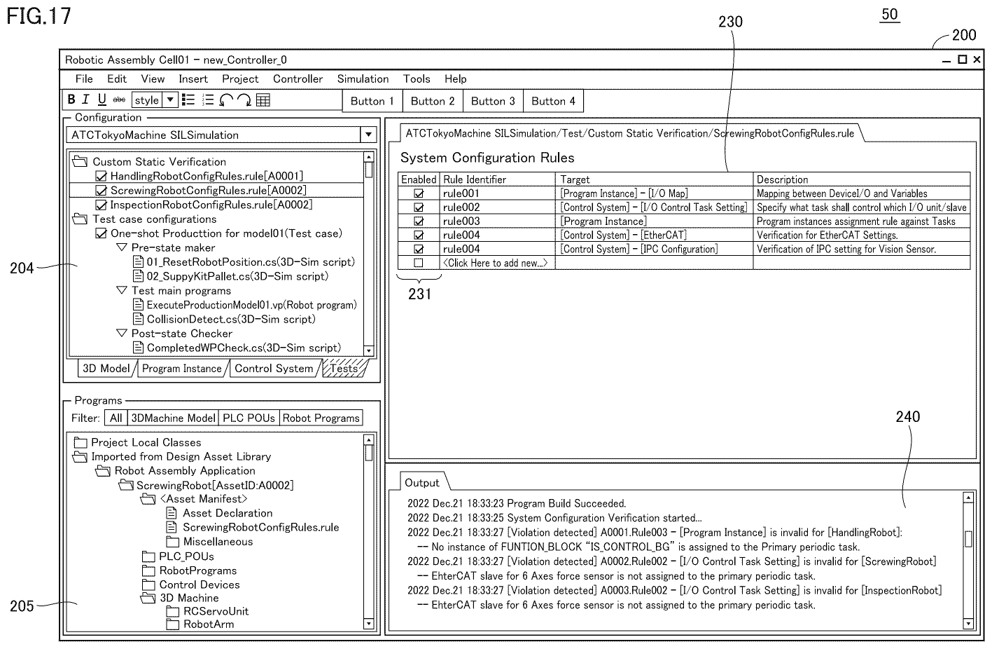

Information processing apparatus 100 outputs verification results 240 obtained through the verification process to an output window of user interface screen 200 (step S204) (see FIG. 17 described later).

Information processing apparatus 100 displays a portion that does not conform to the verification rules in response to a user's operation performed on verification results 240 output to the output window (step S206), and accepts a change operation to control system configuration 60 from the user (step S208).

Information processing apparatus 100 repeats the process of step S206 and the following processes until it is instructed to end the change operation to control system configuration 60 (NO at step S210).

FIG. 17 is a schematic diagram showing an example of user interface screen 200 regarding output of the verification results provided by information processing apparatus 100 according to the present embodiment. Referring to FIG. 17, when the condition for starting verification is satisfied, verification is performed based on the set verification rules.

Verification results 240 are displayed in the output window of user interface screen 200. Verification results 240 may include information for specifying a portion that does not conform to the verification rules. When the verification rules that have been determined not to conform to the verification rules result from design asset 20, verification results 240 may include the information for specifying this design asset 20.

When the item of an error included in verification results 240 is selected, the portion in which the selected error has occurred may be displayed.

In verification (step S202 in FIG. 16) based on the verification rules (system configuration rules 70), at least one of four associations 61, 62, 63, 64 shown in FIG. 8 may be verified. In other words, information processing apparatus 100 verifies at least one of (1) association 61 between a control device and a task, (2) association 62 between a task and a control target, (3) association 63 between a process data object of a control device and a variable, and (4) association 64 between a process data object of a control device and a mechanical configuration.

In the verification (step S202 in FIG. 16) based on the verification rules (system configuration rules 70), the following procedure may be performed.

### (1) Check of System Configuration Rules 70 for Each Design Asset 20

Information processing apparatus 100 selects system configuration rules 70 for each design asset 20 applied to the created control system configuration 60. Information processing apparatus 100 performs the following verification according to the selected system configuration rules 70.

### (1-1) Existence Check of Control Device Required

Information processing apparatus 100 extracts a control device provided with a role ID from the control device configuration of control system configuration 60, for each definition 71 of a control device (see FIG. 9) included in system configuration rules 70. Information processing apparatus 100 performs the following verification for each control device extracted.

### (1-1-1) Conformance Check of Topology for Each Control Device

Information processing apparatus 100 determines whether the extracted control device agrees with any of the control devices whose applicability has been confirmed and which are defined in list 731 (see FIG. 10) of topological rule 73 included in system configuration rules 70. When the extracted control device does not agree with any of the control devices whose application has been confirmed, information processing apparatus 100 outputs an error message indicating non-conformance to topological rule 73, together with the rule ID.

Thus, information processing apparatus 100 determines, in the created control system configuration 60, whether any other control device connected to the low order of the controller defined in control system device configuration 26 conforms to the topological rule.

### (1-1-2) Conformance Check of Low-Order Connection Device for Each Control Device

Information processing apparatus 100 determines whether a control device (a control device provided with a designated role ID) defined in list 732 (see FIG. 9) of topological rule 73 included in system configuration rules 70 exists at the low order of the extracted control device. When the control device defined in list 732 does not exist, information processing apparatus 100 outputs an error message indicating non-conformance to topological rule 73, together with the rule ID.

### (1-1-3) Conformance Check of Task Configuration Rule 76 for Each Control Device

Information processing apparatus 100 determines whether the task designated in task configuration rule 76 which is associated with the extracted control device exists in the extracted control device. When the task designated in task configuration rule 76 does not exist in the control device, information processing apparatus 100 outputs an error message indicating non-conformance to task configuration rule 76, together with the rule ID.

Thus, information processing apparatus 100 determines, in the created control system configuration 60, whether the task assigned to the controller defined in control system device configuration 26 agrees with the task defined in control software configuration 28.

### (1-1-3-1) Task Class, Cycle Period, Priority

Information processing apparatus 100 determines whether the task class, cycle period, and priority of the task that exists in the control device conform to task configuration rule 76. When the task class, cycle period, and priority do not conform to task configuration rule 76, information processing apparatus 100 outputs an error message indicating non-conformance to task configuration rule 76, together with the rule ID.

### (1-1-3-2) Program Assignment

Information processing apparatus 100 determines whether program assignment of the task that exists in the control device conforms to task configuration rule 76. When the program assignment of the task does not conform to task configuration rule 76, information processing apparatus 100 outputs an error message indicating non-conformance to task configuration rule 76, together with the rule ID.

### (1-1-3-3) Exclusive Access Setting of Inter-Task Shared Variable

Information processing apparatus 100 determines whether the exclusive access settings of the inter-task shared variable of the task that exists in the control device conform to task configuration rule 76. When the exclusive access settings of the inter-task shared variable of the task do not conform to task configuration rule 76, information processing apparatus 100 outputs an error message indicating non-conformance to task configuration rule 76, together with the rule ID.

### (1-1-3-4) Control Target (Control Device) of Task

Information processing apparatus 100 determines whether the control target (control device) of the task that exists in the control device conforms to task configuration rule 76. When the control target does not conform to task configuration rule 76, information processing apparatus 100 outputs an error message indicating non-conformance to task configuration rule 76, together with the rule ID.

### (2) Check of PDO Mapping for Each Control Device

Information processing apparatus 100 determines whether PDO mapping of the control device conforms to PDO mapping rule 72 (see FIG. 9). When the PDO mapping of the control device does not conform to PDO mapping rule 72, information processing apparatus 100 outputs an error message indicating non-conformance to PDO mapping rule 72, together with the rule ID.

Thus, information processing apparatus 100 determines, in the created control system configuration 60, whether the contents of the PDO of the controller defined in control system device configuration 26 conform to PDO mapping rule 72.

### (2-1) Variable Assignment Check for Each PDO Entry

Information processing apparatus 100 determines whether the variable associated with the PDO entry of the control device agrees with the variable name defined in mechanical element definition 75 (see FIG. 9). When the variable associated with the PDO entry of the control device does not agree with the variable name defined in mechanical element definition 75, information processing apparatus 100 outputs an error message indicating non-conformance to mechanical element definition 75, together with the rule ID.

Thus, information processing apparatus 100 determines, in the created control system configuration 60, whether the mechanical element mapped to the PDO of the controller defined in control system device configuration 26 conforms to mechanical element definition 75.

### (2-2) Mechanical Element Association Check for Each PDO Entry

Information processing apparatus 100 determines whether the mechanical element (e.g., a sensor and an actuator) associated with the PDO entry of the control device has the role ID defined in mechanical element definition 75 (see FIG. 9). When the mechanical element associated with the PDO entry of the control device does not have the role ID defined in mechanical element definition 75, information processing apparatus 100 outputs an error message indicating non-conformance to mechanical element definition 75, together with the rule ID.

In the verification based on system configuration rules 70 (verification rules), only some of the processes described above may be performed, or the processes other than the processes described above may be performed.

### <I. Advantageous Effects>

High technical skill is required to construct automated equipment (in particular, robot-applied equipment including a robot). Thus, design asset 20 in which apparatuses constituting equipment are configured as a library is provided so as to reduce the level of necessary technical skill and enable efficient design and construction of equipment.

At least a mechanical element, a control device, and software are required to actually construct equipment. For each equipment, there are often specific constraints on a control system. It is complicated work to determine whether the created control system configuration satisfies such specific constraints. If there is any oversight, the control system based on the created control system configuration may fail to exhibit the performance as intended.

In the present embodiment, design asset 20 includes system configuration rules 70, and the created control system configuration is verified based on the verification rules including at least one of system configuration rules 70. As the design system performs verification based on the verification rules, design of the equipment can be increased in efficiency, and the possibility of a fault or the like included in the control system configuration can be reduced.

Design asset 20, which is computer-readable data described in the extensible markup language (XML) format, for example, includes system configuration rules 70 in addition to the design asset ID and revision information.

In any equipment design environment, when the designer creates BOE 12 that is equipment design information, the design asset ID for specifying one or more design assets 20 to be applied is recorded in BOE 12. In control system development environment 50, in use of BOE 12, one or more target design assets 20 are applied based on, for example, the design asset ID recorded in BOE 12. Subsequently, in control system development environment 50, control system configuration 60 is created based on BOE 12 and the one or more applied design assets 20. Further, the created control system configuration 60 is verified based on the verification rules. As a result of the verification, an error that exists in control system configuration 60 may be notified to the designer, or a suggestion to correct the notified error may be provided to the designer.

Although the embodiments of the present disclosure have been described, it should be understood that the embodiments disclosed herein are illustrative and non-restrictive in every respect. The technical scope of the present disclosure is defined by the scope of the claims, and is intended to include any modifications within the meaning and scope equivalent to the terms of the claims.

What is claimed is:

1. A design system for creating a control system configuration, the control system being design information for constructing equipment including one or more apparatuses, the design system being configured to perform:
a process of obtaining equipment design information of the equipment; and
a process of obtaining from a design asset library, based on identification information included in the equipment design information, a design asset for constructing a specific apparatus, wherein
the design asset includes one or more system configuration rules,
the design system is further configured to perform:
a process of creating a control system configuration based on the equipment design information and the design asset; and
a process of verifying the created control system configuration based on one or more verification rules including at least one of the system configuration rules.

2. The design system according to claim 1, wherein the design asset includes
a mechanical configuration that defines a mechanical element necessary for the specific apparatus,
a control system device configuration that defines a control device necessary for operating the specific apparatus, and
a control software configuration that defines software for operating the specific apparatus.

3. The design system according to claim 2, wherein the process of verifying includes a process of verifying at least one of
an association between the mechanical element defined in the mechanical configuration and the control device defined in the control system device configuration, or
an association between the control device defined in the control system device configuration and the software defined in the control software configuration.

4. The design system according to claim 2, wherein the design system is further configured to perform a process of adding, according to a user's operation, a selected rule among the system configuration rules included in the design asset to the verification rules.

5. The design system according to claim 2, wherein the process of verifying includes a process of determining, in the created control system configuration, whether a task assigned to a controller defined in the control system device configuration agrees with a task defined in the control software configuration.

6. The design system according to claim 2, wherein the process of verifying includes a process of determining, in the created control system configuration, whether contents of a process data object of a controller defined in the control system device configuration conform to a mapping rule.

7. The design system according to claim 2, wherein the process of verifying includes a process of determining, in the created control system configuration, whether a mechanical element mapped to a process data object of a controller defined in the control system device configuration conforms to a mechanical element definition.

8. The design system according to claim 2, wherein the process of verifying includes a process of determining, in the created control system configuration, whether any other control device connected to a low order of a controller defined in the control system device configuration conforms to a topological rule.

9. A non-transitory computer-readable medium storing thereon a design program for creating a control system configuration, the control system configuration being design information for constructing equipment including one or more apparatuses, the design program causing a computer to:
obtain equipment design information of the equipment; and
obtain from a design asset library, based on identification information included in the equipment design information, a design asset for constructing a specific apparatus, wherein
the design asset includes one or more system configuration rules,
the design program further causes the computer to:
create a control system configuration based on the equipment design information and the design asset; and
verify the created control system configuration based on one or more verification rules including at least one of the system configuration rules.

10. The non-transitory computer-readable medium according to claim 9, wherein the design asset includes
a mechanical configuration that defines a mechanical element necessary for the specific apparatus,
a control system device configuration that defines a control device necessary for operating the specific apparatus, and
a control software configuration that defines software for operating the specific apparatus.

11. The non-transitory computer-readable medium according to claim 10, wherein the verifying includes verifying at least one of
an association between the mechanical element defined in the mechanical configuration and the control device defined in the control system device configuration, and
an association between the control device defined in the control system device configuration and the software defined in the control software configuration.

12. The non-transitory computer-readable medium according to claim 10, wherein the program further causes the computer to add, according to a user's operation, a selected rule among the system configuration rules included in the design asset to the verification rules.

13. The non-transitory computer-readable medium according to claim 10, wherein the verifying includes determining, in the created control system configuration, whether a task assigned to a controller defined in the control system device configuration agrees with a task defined in the control software configuration.

14. The non-transitory computer-readable medium according to claim 10, wherein the verifying includes determining, in the created control system configuration, whether contents of a process data object of a controller defined in the control system device configuration conform to a mapping rule.

15. A design method performed by a computer for creating a control system configuration, the control system being design information for constructing equipment including one or more apparatuses, the design method comprising:
obtaining equipment design information of the equipment; and
obtaining from a design asset library, based on identification information included in the equipment design information, a design asset for constructing a specific apparatus, wherein
the design asset includes one or more system configuration rules,
the design method further comprising:
creating a control system configuration based on the equipment design information and the design asset; and
verifying the created control system configuration based on one or more verification rules including at least one of the system configuration rules.

16. The design method according to claim 15, wherein the design asset includes
a mechanical configuration that defines a mechanical element necessary for the specific apparatus,
a control system device configuration that defines a control device necessary for operating the specific apparatus, and
a control software configuration that defines software for operating the specific apparatus.

17. The design method according to claim 16, wherein the verifying includes verifying at least one of
an association between the mechanical element defined in the mechanical configuration and the control device defined in the control system device configuration, and
an association between the control device defined in the control system device configuration and the software defined in the control software configuration.

18. The design method according to claim 16, further comprising adding, according to a user's operation, a selected rule among the system configuration rules included in the design asset to the verification rules.

19. The design method according to claim 16, wherein the verifying includes determining, in the created control system configuration, whether a task assigned to a controller defined in the control system device configuration agrees with a task defined in the control software configuration.

20. The design method according to claim 16, wherein the verifying includes determining, in the created control system configuration, whether contents of a process data object of a controller defined in the control system device configuration conform to a mapping rule.
